(19) United States
(12) Patent Application Publication
(10) Pub. No.: US 2019/0159361 A1
(43) Pub. Date: May 23, 2019

(54) AERODYNAMIC AIRBORNE NOISE ABSORBER MODULE

(71) Applicant: QUANTA COMPUTER INC., Taoyuan City (TW)

(72) Inventors: Chao-Jung CHEN, Taoyuan City (TW); Yu-Nien HUANG, Taoyuan City (TW); Herman TAN, Taoyuan City (TW); Chih-Wei LIN, Taoyuan City (TW)

(21) Appl. No.: 15/949,423

(22) Filed: Apr. 10, 2018

Related U.S. Application Data
(60) Provisional application No. 62/587,919, filed on Nov. 17, 2017.

(51) Int. Cl. H05K 7/20; H05K 7/14; G10K 11/162

(52) U.S. Cl. CPC H05K 7/20172; G10K 11/162; H05K 7/1489; H05K 7/20736

(57) ABSTRACT

An apparatus is provided that includes a first distal end and a second distal end. The apparatus also includes a first connecting member located at the first distal end and a second connecting member located at the second distal end. The apparatus also includes at least one bracket secured within the apparatus at the first and second connecting members. The bracket includes a flow guiding depressions and micro pores. The apparatus also includes a plate configured to abut the bracket within the apparatus. The first and second connecting members are configured to connect the apparatus within a server device.

### CROSS-REFERENCE TO RELATED APPLICATIONS

This application claims priority to and the benefit of U.S. Provisional Patent Application No. 62/587,919, entitled “AERODYNAMIC AIRBORNE NOISE ABSORBER MODULE” and filed Nov. 17, 2017, the contents of which are herein incorporated by reference in their entirety as if fully set forth herein.

### FIELD OF THE INVENTION

The present disclosure relates to an apparatus for suppressing noise emanating from individual electronic units within a server device.

### BACKGROUND

The operation of a server system produces unnecessary heat. If the unnecessary heat produced during the operation of the server system is not removed, the efficiency of the server system will be compromised, and in turn the server system will be damaged. Typically, a fan is installed in the server system to dissipate heat and cool the server system.

With the increase in the operating speed of server systems, the heat produced during the operation of the server system is greatly increased. A high-speed fan is introduced to remove the unnecessary heat produced by the server system. However, noise made by the high-speed fan is louder than that of a typical fan. In light of these reasons, an optimization design for simultaneously noise reduction and heat dissipation of a computer system is imperative.

One method of enhancing heat dissipation efficiency is to increase or accelerate airflow through the server system. However, the stronger the airflow, the more turbulent and noisy wake flow may be. The wake is the region of disturbed flow (often turbulent) downstream of a solid body moving through a fluid, caused by the flow of the fluid around the body. Thus, a server system manufacturer faces a design challenge between noise and heat dissipation efficiency.

### SUMMARY

The following presents a simplified summary of one or more embodiments in order to provide a basic understanding of present technology. This summary is not an extensive overview of all contemplated embodiments of the present technology, and is intended to neither identify key or critical elements of all examples, nor delineate the scope of any or all aspects of the present technology. Its sole purpose is to present some concepts of one or more examples in a simplified form as a prelude to the more detailed description that is presented later.

Embodiments of the disclosure concern an apparatus for reducing noise resulting from a plurality of fans in a computing device. An apparatus is provided that includes a first distal end and a second distal end. The apparatus also includes a first connecting member located at the first distal end and a second connecting member located at the second distal end. The apparatus also includes at least one bracket secured within the apparatus at the first and second connecting members. The bracket includes a flow guiding depressions and micro pores. The apparatus also includes a plate configured to abut the bracket within the apparatus. The first and second connecting members are configured to connect the apparatus within a server device.

In some embodiments of the disclosure, the bracket can be made of sheet metal formed using at least one of bending, forming, and stamping. In alternative embodiments of the disclosure, the bracket can be made up of sound absorbing material. Furthermore, the apparatus can include two brackets secured within the apparatus at the first and second connecting members. In some embodiments of the disclosure, each of the flow guiding depressions can be a dome-shaped depression. In some embodiments of the disclosure, the micro pores can be located exclusively within the flow guiding depressions. In alternative embodiments of the disclosure, the micro pores can be located throughout the bracket to create a porous structure.

In some embodiments of the disclosure, the apparatus can also include sound absorbing material housed between the bracket and the plate. In some embodiments of the disclosure, each of the flow guiding depressions can be a conical-shaped depression.

Embodiments of the disclosure concern a computing device for reducing noise resulting from a plurality of fans. The computing device includes a row of drive bays configured to receive hard disk drives. Each of the hard disk drives can be separated by a gap. The computing device can also include an apparatus. The apparatus includes a first distal end and a second distal end. The apparatus also includes a first connecting member located at the first distal end and a second connecting member located at the second distal end. The apparatus also includes at least one bracket secured within the apparatus at the first and second connecting members. The bracket includes a flow guiding depressions and micro pores. The apparatus also includes a plate configured to abut the bracket within the apparatus. The first and second connecting members are configured to connect the apparatus within the computing device.

The computing device can also include fan modules positioned opposite of the plurality of hard disk drives within the computing device. In some embodiments of the disclosure, the apparatus can be located within a critical distance from the fan modules such that a sound wave length is prevented from forming before contacting any surface within the flow guiding depressions. In some embodiments of the disclosure, each of the flow guiding depressions can be positioned at the gap between the hard disk drives.

### BRIEF DESCRIPTION OF THE DRAWINGS

FIG. 1 is a top isometric view of a server device that includes hard drive disk airflow according to an embodiment;

FIG. 2 shows a simplified block diagram of an aerodynamic noise absorber apparatus in the system according to an embodiment;

FIG. 3 shows a top isometric view of a server device that includes a plurality of aerodynamic noise absorber apparatuses according to an embodiment;

FIG. 4A shows a front isometric view of the apparatus for enhancing the hard disk drive performance by resolving the issue between noise, heat dissipation efficiency and HDD read/write performance according to an embodiment;

FIG. 4B shows a rear isometric view of the apparatus for enhancing the hard disk drive performance by resolving the issue between noise, heat dissipation efficiency and HDD read/write performance according to an embodiment;

FIG. 5 shows a top view of a server device incorporating the apparatus of FIGS. 4A and 4B according to an embodiment;

FIG. 6 shows a top view of the apparatus within the server device exemplifying reflected noise according to an embodiment;

FIG. 7 shows side view of the apparatus within the server device exemplifying the reflected noise according to an embodiment;

FIG. 8A shows a top view of the apparatus receiving direct airflow from a fan according to an embodiment;

FIG. 8B shows a side view of the apparatus receiving direct airflow from the fan according to an embodiment; and

FIG. 9 is a top view of the apparatus in the server device according to an embodiment.

### DETAILED DESCRIPTION

The present invention is described with reference to the attached figures, wherein like reference numerals are used throughout the figures to designate similar or equivalent elements. The figures are not drawn to scale, and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

As previously explained, it is common to introduce increased or accelerated airflow through a server system to remove the overwhelming heat produced by the components within the server system. However, stronger airflows can be more turbulent and introduce a significant amount of noise or vibration. This increased vibration and noise can cause reduced HDD read/write performance. In order to balance noise, heat dissipation efficiency, and HDD read/write performance, embodiments of the present invention provide an aerodynamic noise absorber apparatus (hereinafter referred to as “apparatus”) for hard drive disk airflow. In this disclosure, the apparatus serves as an aerodynamic device with sound absorbing flow guiding depressions to enhance hard disk drive performance by resolving the issue between noise, heat dissipation efficiency, and HDD read/write performance. Specifically, the flow guiding depressions are configured to not disrupt the airflow while providing a sound barrier of the plurality of fan modules to the storage array module. The apparatus is positioned at a critical distance from the plurality of fan modules to maximize noise wave absorption.

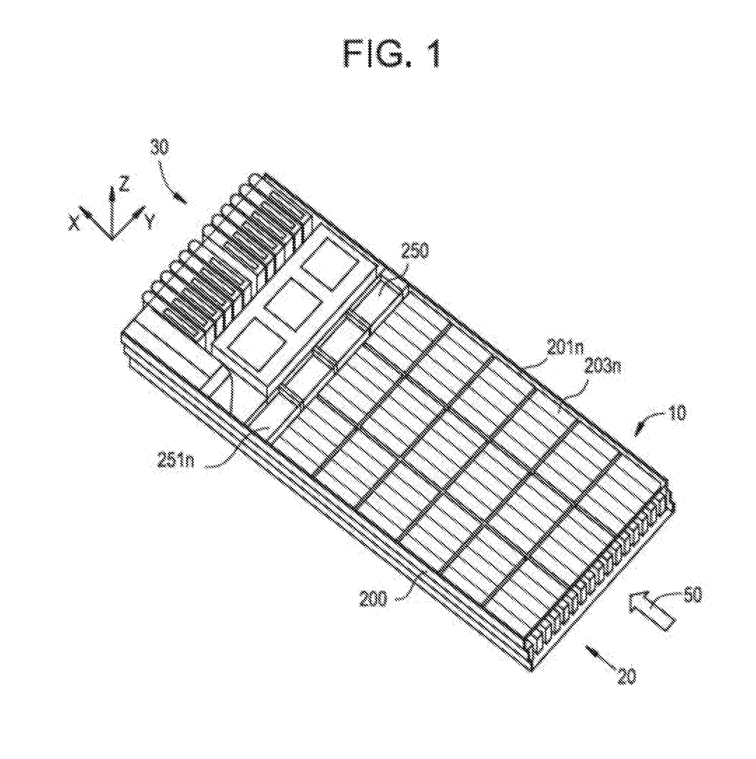

FIG. 1 is a top isometric view of a server device 10 exemplifying airflow 50 according to an embodiment. In some embodiments, the server device 10 includes a plurality of fan modules 250 and a storage array module 200. The server device 10 can include a front end 20 and a rear end 30. The airflow 50 can come across the server device 10 and the encompassed storage array module 200, from the front end 20 to the rear end 30, via the plurality of fan modules 250. It should be understood that the server device 10 includes other components not mentioned herein. The components mentioned above are only for example, and not to limit this disclosure. The person having ordinary knowledge in the art may flexibly include other components in accordance to the invention.

In some embodiments, the storage array module 200 is disposed in the server device 10. To maximize storage, the storage array module 200 can include a plurality of storage arrays 201n closely stacked together. The space 202 between the plurality of storage arrays 201n is very small, to maximize the number of storage arrays 201n. In FIG. 1, the storage array module 200 can include eighteen storage arrays closely stacked together. Each of the storage arrays contains a plurality of disk devices 203n. The plurality of disk devices 203n can include hard disk drive, solid state disk drives, or a combination thereof. Furthermore, for the purpose of this invention, the plurality of disk devices 203n can include other drive technology not detailed herein. In FIG. 1, the plurality of disk devices can include ninety hard disk drives. It should be realized that the quantities of the storage arrays (e.g., eighteen) and disk devices (e.g., ninety) mentioned above are only for example, and not to limit this disclosure. The person having ordinary knowledge in the art may flexibly select any proper quantity of storage arrays according to the requirement.

The plurality of fan modules 250 in the server device 10 is arranged in parallel. In an embodiment of the invention, the plurality of fan modules 250 is disposed near the storage array module 200 to cool the storage array module 200 via convection. The plurality of fan modules 250 is utilized to enhance the air convection across the server device 10 from the front end 20 to the rear end 30. The plurality of fan modules 250 can include four high-powered computer device fans (hereinafter referred to as “fan”) 251N. Thus, the airflow 50 generated by each fan 251N flows into and out of the server device 10 along an x-axis though the plurality of storage arrays 201n closely stacked together. Wake flow is generated by the blades of each of the plurality of fan modules 250 blowing on interior surfaces and other components of the server device 10. A blasting point is generated and regarded as a sound source that generates a band noise.

Consequently, for efficiency, the airflow 50 flowing along the x-axis in the present embodiment is increased by increasing the rotational speeds of each of the plurality of fan modules 250. Airflow 50 is increased to effectively cool between the nominal spaces between the plurality of storage arrays 201n. This enables the plurality of fan modules 250 to maintain the storage array module 200 at the desired operating temperature. However, the more the rotational speed and the flow rate are increased, the higher the frequency of the noise band. Furthermore, each of the plurality of fan modules 250 is loud when operating. The noise comes from not only the fan itself, but also the quantity of the magnetic poles, revolutions, blades of the fan, and combinations thereof. Therefore, the desire to cool the storage array module 200 with increased airflow 50 leads to an increase in noise. It should be understood that the quantity of the fans (e.g., four) mentioned above is only for example, and not to limit this disclosure. The person having ordinary knowledge in the art may flexibly select any proper quantity of fans in accordance with the disclosure.

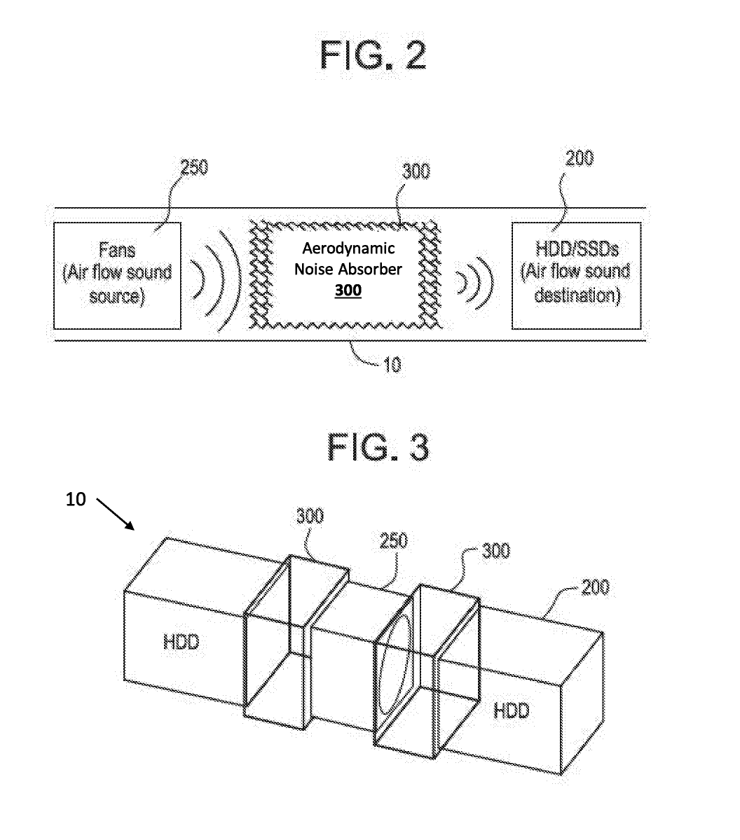

FIG. 2 shows a simplified block diagram of an aerodynamic noise absorber apparatus (hereinafter referred to as “apparatus”) 300 in the server device 10 (in FIG. 1). The apparatus 300 provides a material that enables air flow so as to not disrupt the airflow 50 (in FIG. 1) while providing a sound barrier to the plurality of fan modules 250 of the storage array module 200. As indicated above, a high-speed fan is introduced to remove the unnecessary heat produced by the server device 10. However, noise made by the high-speed fan is louder than the sound produced by a typical fan. As a result, the high-speed fan will generate high sound pressure level (SPL) and cause the HDD performance of reading/writing data to perform poorly. In light of these reasons, the optimization design for noise reducing and heat dissipating of the computer system is imperative. As explained below, the apparatus 300 provides sound reflection, diffraction and absorption to mitigate the noise of the plurality of fan modules 250.

FIG. 3 is a top isometric view of a server device 10 that employs multiple apparatuses 300. In some embodiments, the server device 10 can orient the plurality of fan modules 250 between the storage array modules 200 to improve airflow 50 (in FIG. 1) exhaust from the server device 10. In this case, the server device 10 can employ multiple apparatuses 300 to protect storage array modules 200 oriented on either side of the plurality of fan modules 250. Furthermore, the apparatus 300 can be positioned or relocated with respect to the critical distance, defined below, within the server device 10 to maximize performance of the storage array modules 200 and improve airflow 50 exhaust from the server device 10.

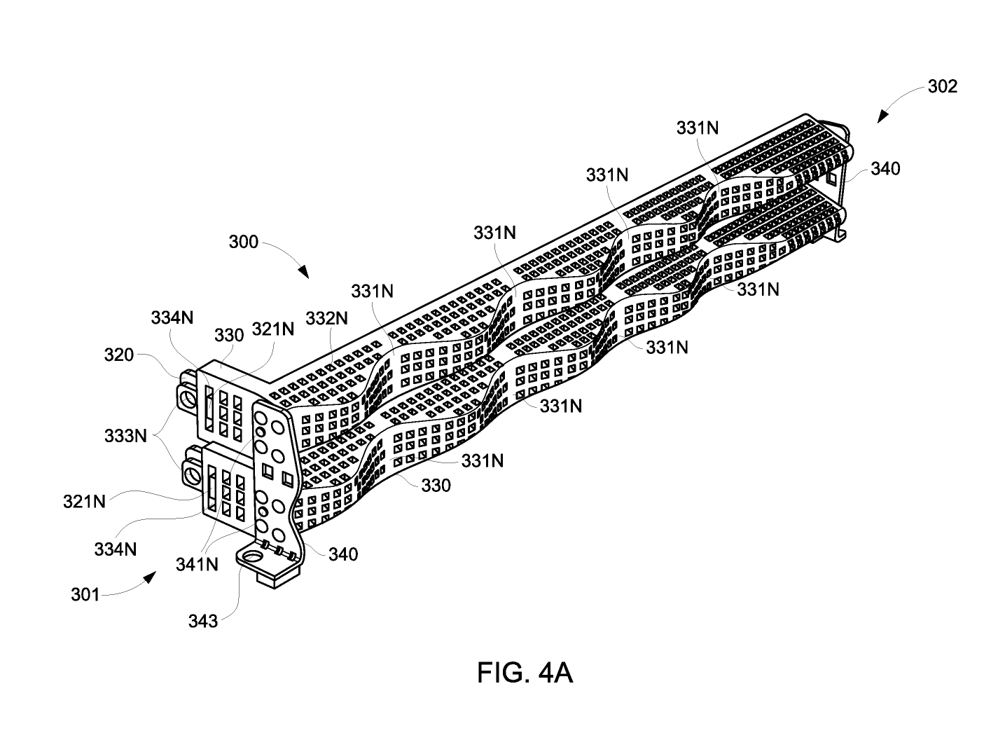

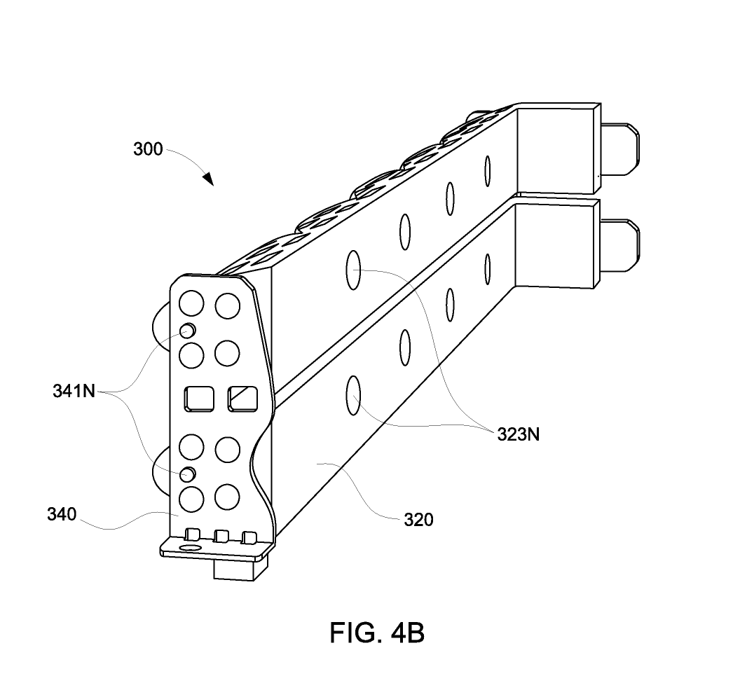

FIG. 4A is a front isometric view of the apparatus 300 for enhancing the hard disk drive performance by resolving the issue between noise, heat dissipation efficiency and HDD read/write performance. FIG. 4B is a rear isometric view of the apparatus 300. The apparatus 300 a first distal end 301 and an opposing distal end 302. The apparatus 300 also includes a bracket 330, a plate 320 abutting the bracket 330, and a connecting member 340 configured to secure the apparatus 300 within an exemplary server device. As shown herein, the apparatus 300 can include multiple brackets 330, with corresponding multiple plates 320, and connecting member 340 connecting the multiple brackets 330. The plate 320 is shown clearly with respect to FIG. 4B.

The plate 320 includes tabs 321N at the first and second distal ends 301 and 302. The bracket 330 can have an opening 334N at the first and second distal ends 301 and 302. The opening 334N can correspond with the tabs 321N. The plate 320 is configured to connect to the bracket 330 via the tabs 321N. The tabs 321N can allow the plate 320 to snap into place on the bracket 330. The plate 320 can also include guide holes 323N. The plate 320 can be fixed to the bracket 330 by incorporating screws, weld points, or other securing methods at the guide holes 323N.

The bracket 330 can include flow guiding depressions 331N. In some embodiments, the flow guiding depressions 331N can be dome-shaped. In alternative embodiments, the flow guiding depressions 331N can be conical-shaped. In some embodiments, the bracket 330 can include micro pores 332N on all of its surfaces. In some embodiments, the micro pores 332N can be located exclusively within the flow guiding depressions 331N. The bracket 330 can also include connecting members 333N. The connecting members 333N can be configured to secure the apparatus 300 to other electronic components within a server device.

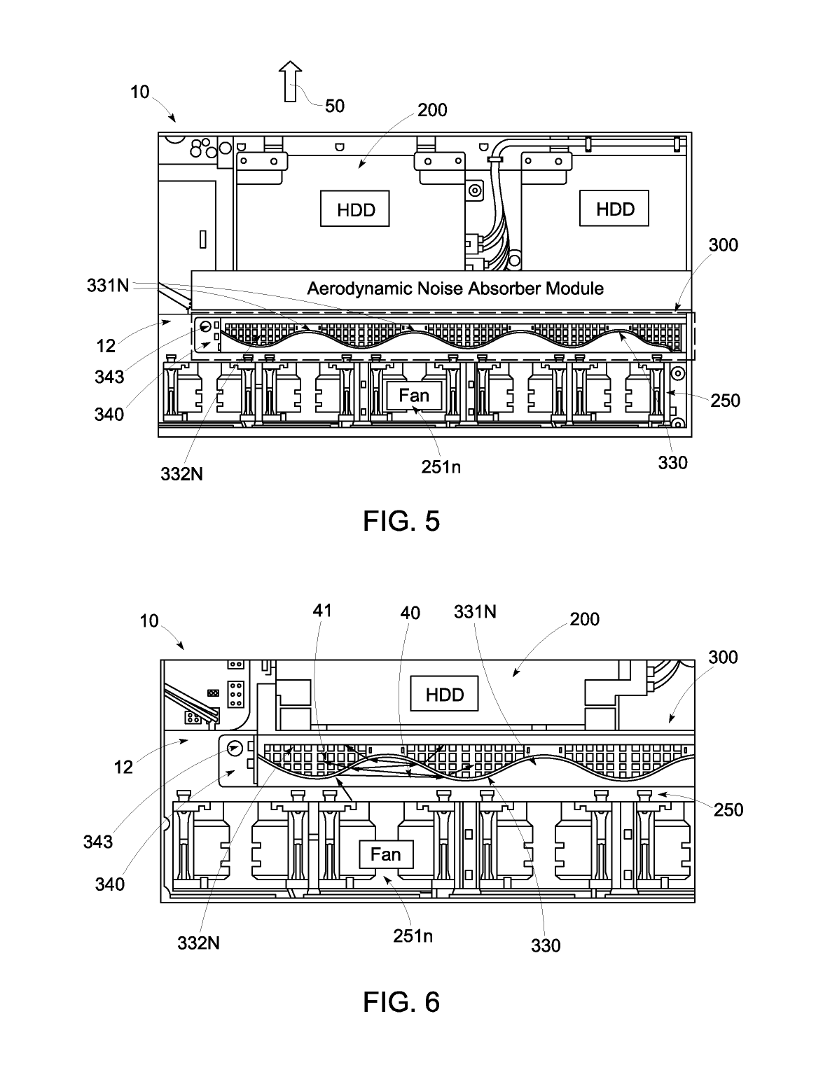

The apparatus 300 can also include at the first and second distal ends 301 and 302 connecting member 340 at the first and second distal ends 301 and 302. The connecting member 340 can be configured to secure multiple brackets 330 within the apparatus 300. Furthermore, the connecting member 340 can secure the apparatus 300 within a server device (not shown). The connecting member 340 can include openings 341N. The openings 341N can be configured to receive a securing element, such as a screw, to secure the connecting member 340 to the brackets 330. The connecting member 340 can also include apertures 343. The apertures 343 can be configured to secure the apparatus 300 to a base within the server device. Securing the apparatus 300 within a server device is shown in more detail with respect to FIG. 5 below.

The bracket 330 and its components can be made of sheet metal using conventional metal fabrication techniques, such as bending, forming, and stamping. As a result, the bracket 330 can be made very inexpensively. In alternative embodiments, the bracket 330 and its components can be made aluminum alloy, steel alloy, or any combination thereof. It should be understood that the bracket 330 and its components can be made of any material constructed to withstand varying temperatures, and air flow of high velocity from high-powered fans.

In some embodiments, the bracket 330 can house sound absorbing material between the bracket 330 and the plate 320. Alternatively, the bracket 330 can be made from sound absorbing material. The sound absorbing material can include glass, wool, urethane foam, and similar materials. Such materials are applicable as all or part of the materials of the plurality of flow guiding depressions 331N and plurality of micro pores 332N. It should be realized that the sound absorber material can be any material constructed to perform with high efficiency in regards to noise reduction. The materials mentioned above are only for example, and not to limit this disclosure. The person having ordinary knowledge in the art may flexibly select any material in accordance with the disclosure.

FIG. 5 is a top view of a server device 10 incorporating the apparatus 300 of FIGS. 4A and 4B. The server device 10 can have a base 12. The server device 10 can also include a plurality of fan modules 250 and a storage array module 200. The apparatus 300 can be positioned between the plurality of fan modules 250 and the storage array module 200. The apparatus 300 can be secured within the server device 10 by the connecting member 340. Specifically, the apparatus 300 can be secured to the base 12 via the aperture 343. In some embodiments, the apparatus 300 can include a number of flow guiding depressions 331N. Furthermore, the plurality of fan modules 250 can include an individual fan 251N.

The flow guiding depressions 331N can be located directly in front of a corresponding fan 251N. In this orientation, airflow 50 can be prevented from being undesirably directed or lost between each of the flow guiding depressions 331N. As a result, the flow guiding depressions 331N are position closely together in alignment with the fan 251N. Each micro pore 332N can be spatially scattered within the bracket 330 to create a highly porous material to allow for air flow 50 through the server device 10. The resulting configuration reflects noise generated by the plurality of fan modules 250 while enabling air flow 50 through the server device 10.

FIG. 6 is a top view of the apparatus 300 within the server device 10 exemplifying reflected noise. As indicated above, noise made by a high-powered computer device fan 251N generates higher noise than a typical fan. Each fan 251N has a blade pass frequency (BPF) within a different range than the hard drive natural frequency of the disk device 203N (shown in FIG. 1) of the storage array modules 200. In some embodiments, the hard drive natural frequency can range from 1200-2500 (Hz). The fan blade pass frequency is highly related to the number of blades of the fan and its rotation per minute during in-system operation. In some embodiments, the noise generated from the plurality of fan modules 250 can be reflected within the flow guiding depressions 331N. In alternative embodiments, the reflected noise 40 can be captured within the bracket 330.

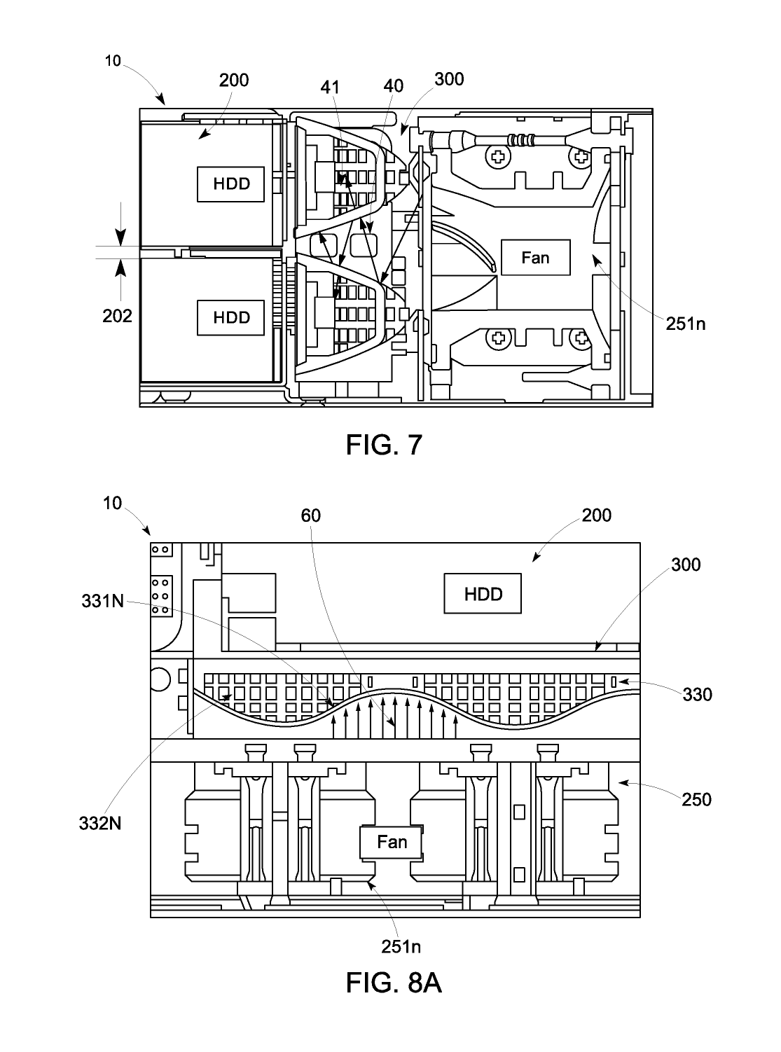

FIG. 7 is a side view of the apparatus 300 within the server device 10 exemplifying the reflected noise. The flow guiding depressions 331N can be configured to dampen the reflected noise 40 waves to create absorbed noise 41 waves. The majority of the reflected noise 40 waves are absorbed within the flow guiding depressions 331N of the bracket 330. As indicated in FIG. 6 little to none of the absorbed noise 41 is allowed to pass through the space 202 between the plurality of storage arrays 201N. Therefore, the presence of the flow guiding depressions 331N can increase the absorbing efficiency of the apparatus 300. Furthermore, the absence of the absorbed waves 41 and the reflected noise 40 in the space 202 maximizes the performance of the HDD reading/writing performance.

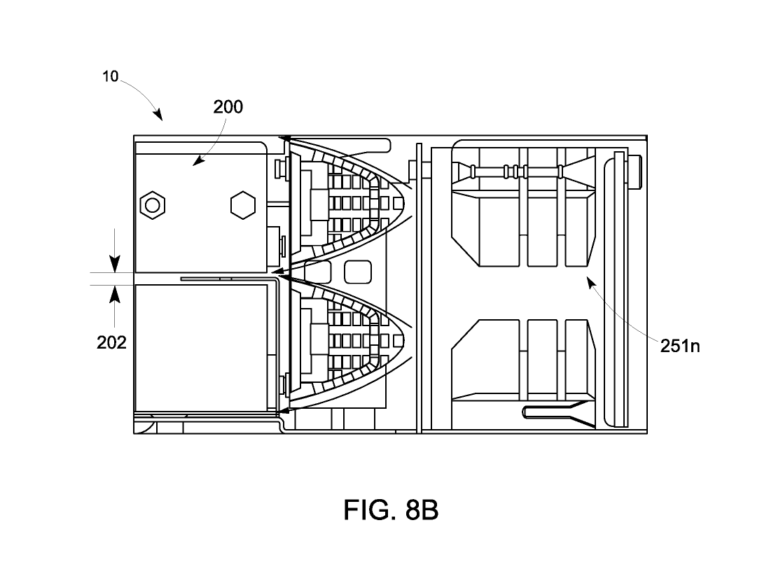

FIG. 8A illustrates a top view of the apparatus 300 receiving direct airflow 60 from the fan 251N. FIG. 8B illustrates a side view of the apparatus 300 receiving direct airflow 60 from the fan 251N. Each of the flow guiding depressions 331N can receive airflow 60 from a corresponding fan 251N. As indicated above, the apparatus 300 includes micro pores 332N. The flow guiding depressions 331N and the micro pores 322N can be configured to allow lower pressure and greater airflow. As discussed above with respect to FIGS. 5 and 6, the flow guiding depressions 331N can minimize the pressure. Furthermore, the micro pores 332N can be configured to trap sound waves resulting from operation of the fan 251N and the airflow 60. The micro pores 332N can also enable an aerodynamic design to ensure the apparatus 300 does not block the airflow 60.

As indicated in FIG. 8B, the airflow 60 is guided along the surface of the flow guiding depressions 331N. As a result of each of the flow guiding depressions 331N positioned in front of each fan 251N, airflow 60 is prevented from being directed or lost between each of the guiding depressions 331N. Furthermore, the flow guiding depressions 331N can be positioned between each of the storage arrays 201N in the space 202. In this embodiment, airflow 60 is prevented from flowing in the space 202 between the storage arrays 201N. In some embodiments, the apparatus 300 is positioned at a calculated distance from the plurality of fan modules 200.

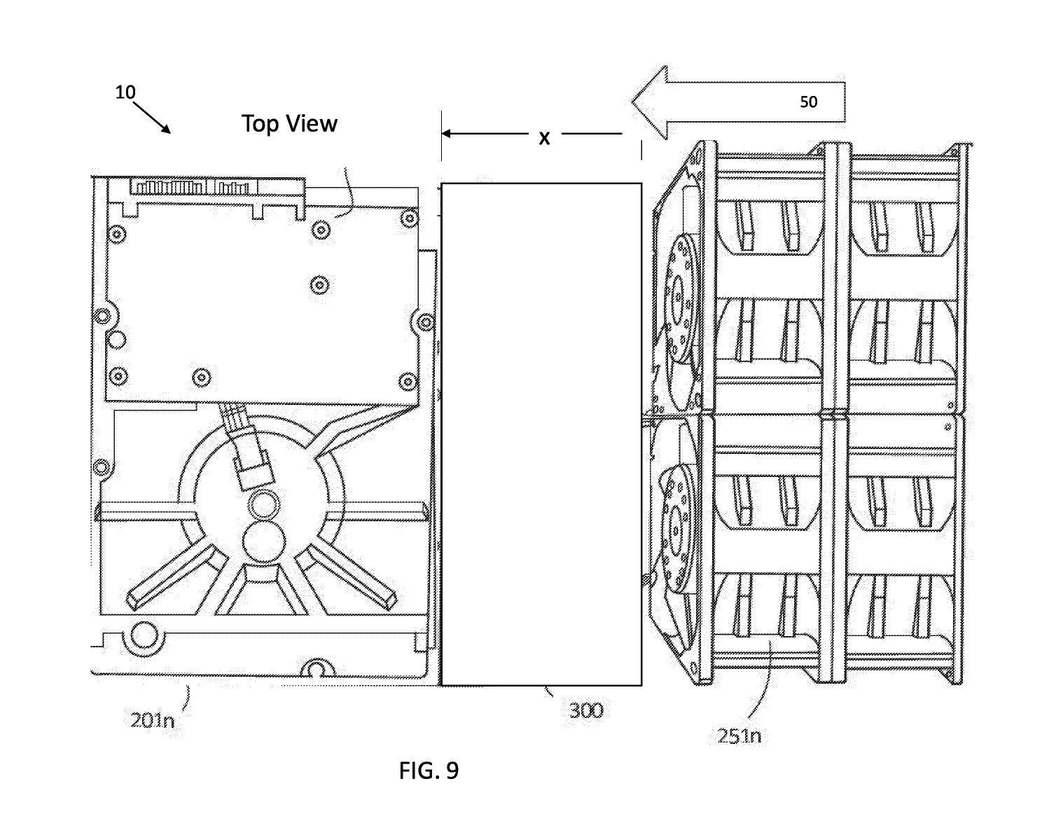

FIG. 9 is a top view of the apparatus 300 in the server device 10 exemplifying a critical distance according to an embodiment of the disclosure. In some embodiments, the placement of the apparatus 300 in the server device 10 directly affects the sound wave length emanating from the plurality of fan modules 250. In some embodiments, a critical distance can be defined as the distance between the apparatus 300 and the plurality of fan modules 250. Specifically, the critical distance can be defined as the maximum distance where the maximum amplitude of the noise wave occurs. In some embodiments, the critical distance can be defined as:

$$x = \frac{5.4 \times {10}^{6}}{n \times v}$$

In the formula above, x represents the distance in millimeters between the apparatus 300 and the plurality of fan modules 250. Moreover, the n represents the number of fan blades incorporated in each fan 251N. As indicated above, the fan blade pass frequency is highly related to the number of fan blades of the fan and its rotation per minute during operation. Value v represents the fan speed in rotations per minute. In some embodiments, 360 meters per second is a normalized sound speed. Furthermore, a typical high-powered computer device fan 251N can rotate at 21600 rotations per minute with five fan blades. As a result, the critical distance between the apparatus 300 and the plurality of fan modules 250 should not exceed 50 millimeters. When the apparatus 300 is placed within the critical distance the noise wave absorption is maximized such that it will not interfere with the natural frequency of the storage array 201N which can cause performance degradation.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The terminology used herein is for the purpose of describing particular embodiments only and is not intended to limit the invention. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

What is claimed is:

1. An apparatus comprising:
a first distal end and a second distal end;
a first connecting member located at the first distal end;
a second connecting member located at the second distal end;
at least one bracket secured within the apparatus at the first and second connecting members, the at least one bracket comprising a plurality of flow guiding depressions and a plurality of micro pores; and
a plate configured to abut the bracket within the apparatus;
wherein first and second connecting members are configured to connect the apparatus within a server device.

2. The apparatus of claim 1, wherein the bracket comprises sheet metal formed using at least one of bending, forming, and stamping.

3. The apparatus of claim 1, wherein the bracket comprises sound absorbing material.

4. The apparatus of claim 1, further comprising two brackets secured within the apparatus at the first and second connecting members.

5. The apparatus of claim 1, wherein each of the plurality of flow guiding depressions comprises a dome-shaped depression.

6. The apparatus of claim 1, wherein the plurality of micro pores is located exclusively within the flow guiding depressions.

7. The apparatus of claim 1, wherein the plurality of micro pores is located throughout the bracket to create a porous structure.

8. The apparatus of claim 1, further comprising sound absorbing material housed between the bracket and the plate.

9. The apparatus of claim 1, wherein each of the plurality of flow guiding depressions comprises a conical-shaped depression.

10. A computing device comprising:
at least one row of drive bays configured to receive a plurality of hard disk drives, each of the hard disk drives separated by a gap; and
an apparatus comprising:
a first distal end and a second distal end;
a first connecting member located at the first distal end;
a second connecting member located at the second distal end;
at least one bracket secured within the apparatus at the first and second connecting members, the at least one bracket comprising a plurality of flow guiding depressions and a plurality of micro pores; and
a plate configured to abut the bracket within the apparatus;
wherein first and second connecting members are configured to connect the apparatus within the computing device.

11. The computing device of claim 10, further comprising a plurality of fan modules positioned within the computing device opposite of the plurality of hard disk drives.

12. The computing device of claim 11, wherein the apparatus is located within a critical distance from the plurality of fan modules such that a sound wave length is prevented from forming before contacting any surface within each of the flow guiding depressions.

13. The computing device of claim 10, wherein each of the plurality of flow guiding depressions is positioned at the gap between the hard disk drives.

14. The computing device of claim 10, wherein the bracket comprises sheet metal formed using at least one of bending, forming, and stamping.

15. The computing device of claim 10, wherein the bracket comprises sound absorbing material.

16. The computing device of claim 10, further comprising two brackets secured within the apparatus at the first and second connecting members.

17. The computing device of claim 10, wherein each of the plurality of flow guiding depressions comprises a dome-shaped depression.

18. The computing device of claim 10, wherein the plurality of micro pores is located exclusively within the flow guiding depressions.

19. The computing device of claim 10, wherein the plurality of micro pores is located throughout the bracket to create a porous structure.

20. The computing device of claim 10, further comprising sound absorbing material housed between the bracket and the plate.

21. The computing device of claim 10, wherein each of the plurality of flow guiding depressions comprises a conical-shaped depression.
